(19) United States
(12) Patent Application Publication
(10) Pub. No.: US 2023/0054117 A1
(43) Pub. Date: Feb. 23, 2023

(54) ELECTRO-STATIC DISCHARGE PROTECTION DEVICE FOR SEMICONDUCTOR

(71) Applicant: Changxin Memory Technologies, Inc., Hefei City (CN)

(72) Inventor: Qian XU, Hefei City (CN)

(21) Appl. No.: 17/658,285

(22) Filed: Apr. 7, 2022

(30) Foreign Application Priority Data
Aug. 19, 2021 (CN) 202110956959.2

(51) Int. Cl. H01L 27/02; H02H 9/04

(52) U.S. Cl. CPC H01L 27/0255; H01L 27/0292; H01L 27/0296; H02H 9/046; H01L 23/50

(57) ABSTRACT

The present disclosure provides an electro-static discharge protection device for a semiconductor, including: a substrate of a first conductive type, a deep well region of a second conductive type being formed in the substrate of the first conductive type; first diodes, located in the deep well region of the second conductive type, anodes of the first diodes being connected to a first voltage through a plurality of first metal lines; second diodes, located in the deep well region of the second conductive type; a first pad, connected to the anodes of the first diodes through the plurality of first metal lines, and connected to the first voltage; a second pad, connected to cathodes of the second diodes through a plurality of second metal lines, and connected to a second voltage.

### CROSS-REFERENCE TO RELATED APPLICATION

This application claims the priority of Chinese Patent Application No. 202110956959.2, submitted to the Chinese Intellectual Property Office on Aug. 19, 2021, the disclosure of which is incorporated herein in its entirety by reference.

### TECHNICAL FIELD

The present disclosure relates to the technical field of semiconductors, in particular to an electro-static discharge protection device for a semiconductor.

### BACKGROUND

In modern times, the manufacture of semiconductors is becoming more advanced, with shorter trenches and shallower junctions. As applications of silicides and lightly doped drain (LDD) processes expand, there are thinner oxide layers, smaller ESD design windows, and greater challenges for ESD protection. Existing ESD protection devices commonly have a poor ESD protection capability, and cannot ensure the reliability of products.

### SUMMARY

The present disclosure provides an electro-static discharge protection device for a semiconductor, including:

a substrate of a first conductive type, a deep well region of a second conductive type being formed in the substrate of the first conductive type;

a first diode, located in the deep well region of the second conductive type, an anode of the first diode being connected to a first voltage through a plurality of first metal lines;

a second diode, located in the deep well region of the second conductive type;

a first pad, connected to the anode of the first diode through the plurality of first metal lines, and connected to the first voltage;

a second pad, connected to a cathode of the second diode through a plurality of second metal lines, and connected to a second voltage; and

an input/output (I/O) pad, connected to an anode of the second diode and a cathode of the first diode through a plurality of third metal lines.

### BRIEF DESCRIPTION OF THE DRAWINGS

To describe the technical solutions in the embodiments of the present disclosure or in the prior art more clearly, the following briefly describes the accompanying drawings required for describing the embodiments or the prior art. Apparently, the accompanying drawings in the following description show some embodiments of the present disclosure, and those of ordinary skill in the art may still derive other drawings from these accompanying drawings without creative efforts.

FIG. 1 is an equivalent circuit diagram of an electro-static discharge protection device for a semiconductor according to the present disclosure;

FIG. 2 is a top view of an electro-static discharge protection device for a semiconductor according to an embodiment of the present disclosure;

FIG. 3 is a schematic sectional view of the electro-static discharge protection device for a semiconductor in FIG. 2;

FIG. 4 is a top view of a substrate of a first conductive type in the electro-static discharge protection device for a semiconductor in FIG. 2; and

FIG. 5 and FIG. 6 are a top view of an electro-static discharge protection device for a semiconductor according to another embodiment of the present disclosure.

### DETAILED DESCRIPTION

To facilitate the understanding of the present disclosure, the present disclosure will be described more completely below with reference to the accompanying drawings. The embodiments of the present disclosure are shown in the drawings. However, the present disclosure may be embodied in various forms without being limited to the embodiments described herein. These embodiments are provided in order to make the present disclosure more thorough and comprehensive.

Unless otherwise defined, all technical and scientific terms used herein have the same meaning as commonly understood by those skilled in the technical field of the present disclosure. The terms mentioned herein are merely for the purpose of describing specific embodiments, rather than to limit the present disclosure.

It is understandable that the terms such as “first” and “second” used herein may be used to describe various elements, but these elements are not limited by these terms. Instead, these terms are merely intended to distinguish one element from another.

It can be understood that “connection” in the following embodiments should be understood as “electrical connection” or “communication connection” if the connected circuits, modules or units have electrical signal or data transmission between each other.

In this specification, the singular forms of “a”, “an” and “the/this” may also include plural forms, unless clearly indicated otherwise. It should also be understood that the terms such as “including/comprising” and “having” indicate the existence of the stated features, wholes, steps, operations, components, parts or combinations thereof. However, these terms do not exclude the possibility of the existence of one or more other features, wholes, steps, operations, components, parts or combinations thereof.

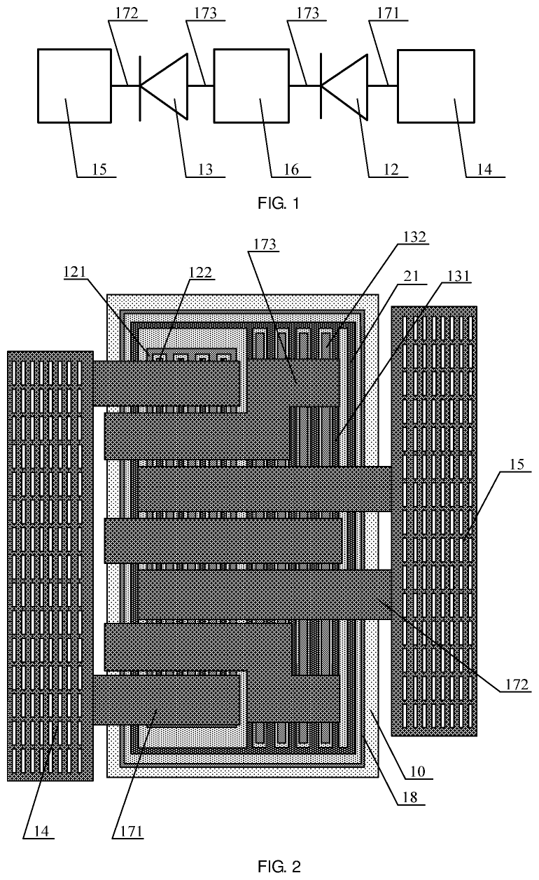

Referring to FIG. 1 to FIG. 4, the present disclosure provides an electro-static discharge protection device for a semiconductor, including: a substrate 10 of a first conductive type, a deep well region 11 of a second conductive type being formed in the substrate 10 of the first conductive type; first diodes 12, located in the deep well region 11 of the second conductive type, anodes of the first diodes 12 being connected to a first voltage through a plurality of first metal lines 171; second diodes 13, located in the deep well region 11 of the second conductive type; a first pad 14, connected to the anodes of the first diodes 12 through the plurality of first metal lines 171, and connected to the first voltage; a second pad 15, connected to cathodes of the second diodes 13 through a plurality of second metal lines 172, and connected to a second voltage; and an I/O pad 16, connected to anodes of the second diodes 13 and cathodes of the first diodes 12 through a plurality of third metal lines 173.

The electro-static discharge protection device for a semiconductor can significantly improve the electro-static discharge protection capability, enlarge the design window of the electro-static discharge protection device, and make the product more reliable, without increasing the layout area.

Specifically, the material of which the substrate 10 of the first conductive type is made may include, but is not limited to silicon, germanium, GaAs (gallium arsenide), InP (indium phosphide) or GaN (gallium nitride) or the like, namely the substrate 10 of the first conductive type may be a silicon substrate, a germanium substrate, a GaAs substrate, an InP substrate or a GaN substrate. In the embodiment, the substrate 10 of the first conductive type may be the silicon substrate.

As an example, a depth of the deep well region 11 of the second conductive type is less than a thickness of the substrate 10 of the first conductive type.

Specifically, the deep well region 11 of the second conductive type may be a lightly doped region.

As an example, the electro-static discharge protection device for a semiconductor further includes: a protective ring 18. The deep well region 11 of the second conductive type is located in the protective ring 18, namely the protective ring 18 surrounds the deep well region 11 of the second conductive type. The protective ring 18 may be spaced apart from the deep well region 11 of the second conductive type.

Specifically, the protective ring 18 may be of the first conductive type, namely the doping type of the protective ring 18 may be the same as that of the substrate 10 of the first conductive type.

In an example, the electro-static discharge protection device for a semiconductor further includes: a doped well region 19 of the first conductive type and a doped well region 20 of the second conductive type. Both the doped well region 19 of the first conductive type and the doped well region 20 of the second conductive type are located in the deep well region 11 of the second conductive type. The first diodes 12 are located in the doped well region 19 of the first conductive type. The second diodes 13 are located in the doped well region 20 of the second conductive type.

Specifically, the doped well region 19 of the first conductive type and the doped well region 20 of the second conductive type each may be a lightly doped region. The doped well region 19 of the first conductive type may be as deep as the doped well region 20 of the second conductive type. More specifically, both the doped well region 19 of the first conductive type and the doped well region 20 of the second conductive type are shallower than the deep well region 11 of the second conductive type.

As an example, the doped well region 19 of the first conductive type abuts against the doped well region 20 of the second conductive type. Specifically, the doped well region 19 of the first conductive type and the doped well region 20 of the second conductive type are arranged along a direction parallel to a surface of the substrate 10 of the first conductive type.

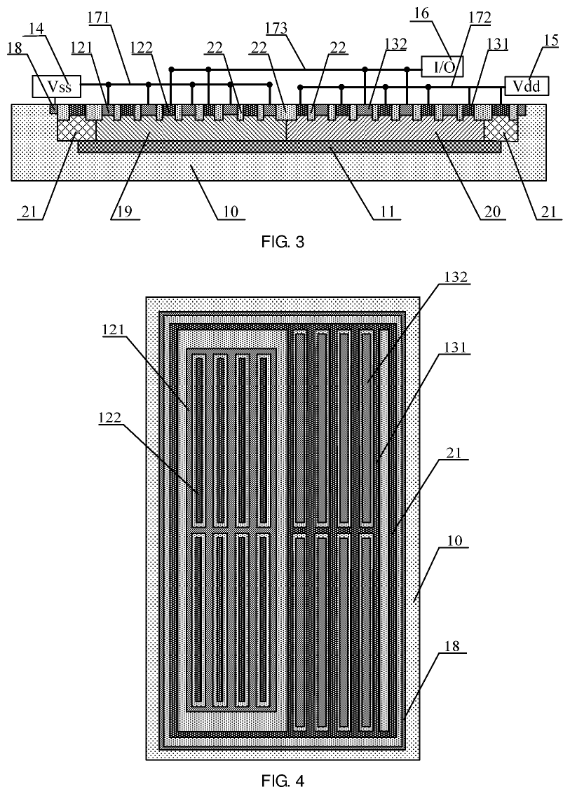

As an example, as shown in FIG. 3, the first diodes 12 each may include a first doped region 121 of the first conductive type and a second doped region 122 of the second conductive type, the first doped region 121 serving as an anode of each of the first diodes 12, and the second doped region 122 serving as a cathode of each of the first diodes 12. The second diodes 13 each may include a third doped region 131 of the second conductive type and a fourth doped region 132 of the first conductive type, the fourth doped region 132 serving as an anode of each of the second diodes 13, and the third doped region 131 serving as a cathode of each of the second diodes 13.

As an example, the first doped regions 121 and the second doped regions 122 of the first diodes may be alternately arranged along a first direction; and the third doped regions 131 and the fourth doped regions 132 of the second diodes may be alternately arranged along the first direction.

As an example, as shown in FIG. 3, the electro-static discharge protection device for a semiconductor further includes a fifth doped region 21 of the first conductive type. The fifth doped region 21 is located in the deep well region 11 of the second conductive type, and around the first diodes 12 and the second diodes 13. Specifically, the fifth doped region 21 may be annular doped regions.

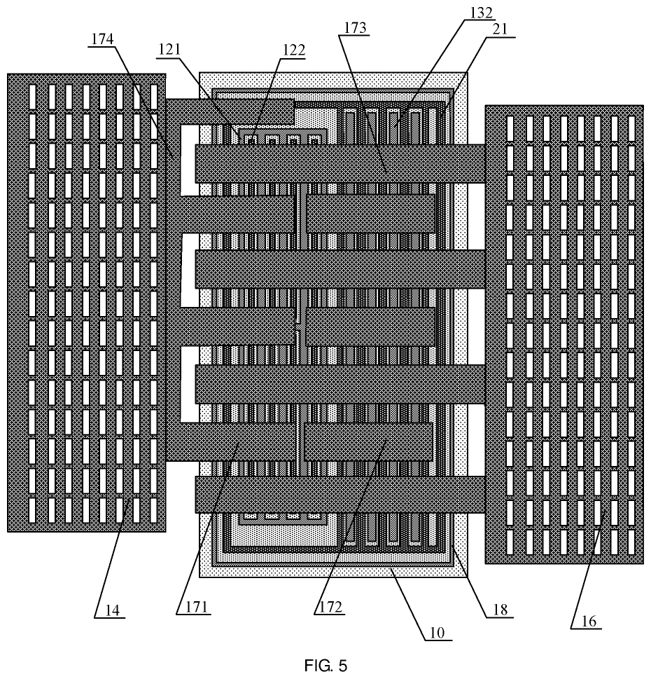

As an example, as shown in FIG. 4, the first doped regions 121 may enclose a plurality of first annular shapes (not shown). The second doped regions 122 are located in the first annular shapes. The third doped regions 131 and the fifth doped region 21 are connected to jointly enclose a plurality of second annular shapes (not shown). The fourth doped regions 132 are located in the second annular shapes.

As an example, the first doped regions 121, the second doped regions 122, the third doped regions 131, the fourth doped regions 132 and the fifth doped region 21 are all shallower than the doped well region 19 of the first conductive type and the doped well region 20 of the second conductive type.

As an example, the first doped regions 121, the second doped regions 122, the third doped regions 131, the fourth doped regions 132 and the fifth doped regions 21 each may be a heavily doped region.

In an example, each of the first annular shapes is provided therein with one of the second doped regions 122, and each of the second annular shapes is provided therein with one of the fourth doped regions 132, as shown in FIG. 4.

In an example, each of the first annular shapes may be provided therein with a plurality of the second doped regions 122. A plurality of second doped regions 122 located in a same first annular shape extend along the second direction, and are spaced apart along the second direction. Each of the second annular shapes is provided therein with a plurality of the fourth doped regions 132. A plurality of fourth doped regions 132 located in a same second annular shape extend along the second direction, and are spaced apart along the second direction. The second direction is perpendicular to the first direction.

In an example, there may be a plurality of first diodes 12 that are sequentially connected in series; and there are a plurality of second diodes 13 that are sequentially connected in series. The number of first diodes 12 and the number of second diodes 13 may be set according to actual needs, and are not defined in the embodiment.

As an example, as shown in FIG. 3, an STI structure 22 is respectively provided between the first doped region 121 and the second doped region 122, between the first doped region 121 and the third doped region 131, and between the third doped region 131 and the fourth doped region 132. Specifically, an STI structure is also provided between the first doped region 121 and the protective ring 18 as well as between the third doped region 131 and the protective ring 18.

Specifically, the longitudinal section of the STI structure 22 may be rectangular, inverted trapezoidal, semi-elliptical or the like.

Specifically, the height of the STI structure 22 is greater than the depth of each of the first doped region 121, the second doped region 122, the third doped region 131, the fourth doped region 132 and the fifth doped region 21, and less than the depth of each of the doped well region 19 of the first conductive type and the doped well region 20 of the second conductive type.

In an example, the first conductive type may be a P type, and the second conductive type may be an N type.

In another example, the first conductive type may be an N type, and the second conductive type may be a P type.

In an example, the first voltage may be a power voltage VDD, and the second voltage may be a ground voltage VSS. That is, the first diodes 12 are provided with the anodes connected to the power terminal and the cathodes connected to the I/O terminal, and the second diodes 13 are provided with the anodes connected to the I/O terminal and the cathodes connected to the ground terminal. Therefore, when the static electricity occurs between the I/O terminal and the power terminal and the voltage generated by electro-static charges is greater than a reverse breakdown voltage of each of the first diodes 12, the electro-static charges are discharged from the first diodes 12. When the static electricity occurs between the I/O terminal and the ground terminal, and the voltage generated by electro-static charges is greater than a forward turn-on voltage of each of the second diodes 13, the electro-static charges are discharged from the second diodes 13.

In another optional embodiment, as shown in FIG. 1 and FIG. 3, the first voltage is the ground voltage Vss, and the second voltage is the power voltage Vdd. That is, the first diodes 12 are provided with the anodes connected to the ground terminal and the cathodes connected to the I/O terminal, and the second diodes 13 are provided with the anodes connected to the I/O terminal and the cathodes connected to the power terminal. Therefore, when the static electricity occurs between the I/O terminal and the power terminal and the voltage generated by electro-static charges is greater than a forward turn-on voltage of each of the first diodes 12, the electro-static charges are discharged from the first diodes 12. When the static electricity occurs between the I/O terminal and the ground terminal, and the voltage generated by electro-static charges is greater than a reverse breakdown voltage of each of the second diodes 13, the electro-static charges are discharged from the second diodes 13.

As an example, as shown in FIG. 2, the first metal lines 171 are located on the first diodes 12, and extend along the first direction. The second metal lines 172 are located on the second diodes 13, and extend along the first direction. The third metal lines 173 are located on the first diodes 12 and the second diodes 13, and extend along the first direction.

It should be noted that the second metal lines 172 may also extend from the second diodes 13 to the first diodes 12 in FIG. 2. Nevertheless, the second metal lines 172 are only connected to the second diodes 13 but not the first diodes 12.

It is further to be noted that the I/O pad 16 to which the third metal lines 173 are connected is not shown in FIG. 2.

Specifically, the number of first metal lines 171, the number of second metal lines 172 and the number of third metal lines 173 may be set according to actual needs. In FIG. 2, there are two first metal lines 171, two second metal lines 172 and three third metal lines 173.

As an example, the first metal lines 171 are in one-to-one correspondence with the second metal lines 172. The first metal lines 171 and the second metal lines 172 are alternately arranged with the third metal lines 173 along a second direction. The second direction is perpendicular to the first direction.

As an example, as shown in FIG. 2, at least one of the first pad 14, the second pad 15 and the I/O pad 16 is of a mesh-like shape. In the embodiment shown in FIG. 2, the first pad 14, the second pad 15 and the I/O pad 16 are of the mesh-like shape.

Specifically, the first metal lines 171, the second metal lines 172 and the third metal lines 173 each may include, but are not limited to copper wires, aluminum wires, gold wires, nickel wires or the like. In the embodiment, the first metal lines 171, the second metal lines 172 and the third metal lines 173 are copper wires.

The failure of the electro-static discharge protection device for the semiconductor lies in metal lines (namely the first metal lines 171, the second metal lines 172 and the third metal lines 173). The electro-static discharge protection device for the semiconductor shown in FIG. 2 has a better electro-static discharge protection capability than the existing electro-static discharge protection device for the semiconductor. However, due to insufficient metal lines and imperfect arrangement of the metal lines, the electro-static discharge protection capability of the electro-static discharge protection device for the semiconductor shown in FIG. 2 is to be improved.

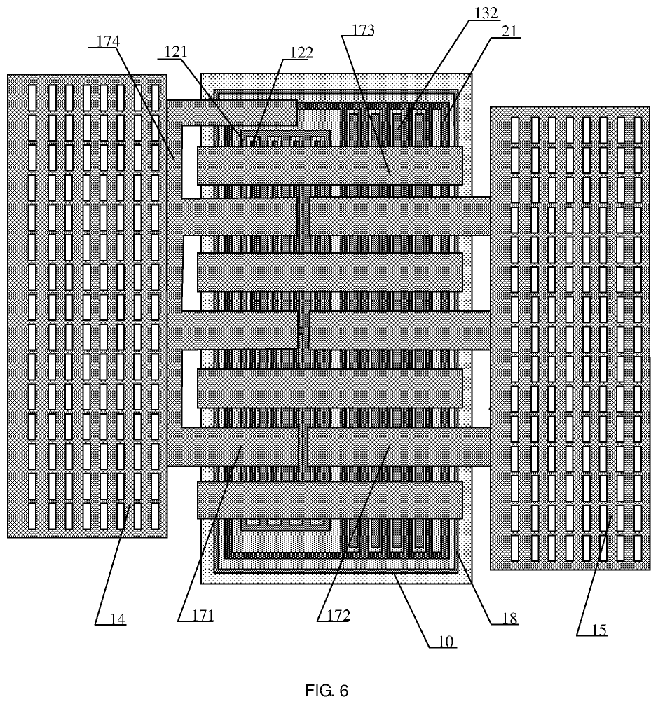

In another embodiment, as shown in FIG. 5 and FIG. 6, except the metal lines, the electro-static discharge protection device for a semiconductor in FIG. 5 and FIG. 6 and the electro-static discharge protection device for a semiconductor in FIG. 1 to FIG. 4 are substantially the same in specific structure.

Specifically, as shown in FIG. 5, the electro-static discharge protection device for a semiconductor further includes: a fourth metal line 174, extending along the second direction, and connected to the plurality of first metal lines 171 to form an interdigital structure with the first metal lines 171.

It should be noted that FIG. 5 and FIG. 6 are formed into the top view of the same electro-static discharge protection device for the semiconductor. The first pad 14, the second pad 15 and the I/O pad 16 are schematically illustrated in FIG. 5 and FIG. 6 because they are not shown in the same figure conveniently.

Specifically, the number of first metal lines 171, the number of second metal lines 172 and the number of third metal lines 173 may be set according to actual needs.

Specifically, in the embodiment, there are three first metal lines 171 connected to the first diodes 12 and four third metal lines 173, as shown in FIG. 5; and there are three second metal lines 172, as shown in FIG. 6. Certainly, in other examples, there may be more first metal lines 171, second metal lines 172 and third metal lines 173.

By adding the fourth metal line 174, and adjusting the number of first metal lines 171, the number of second metal lines 172 and the number of third metal lines 173, the electro-static discharge protection device for a semiconductor in FIG. 5 and FIG. 6 has a better electro-static discharge protection capability.

In the specification, the description of terms such as “one of the embodiments”, “other embodiments” means that a specific feature, structure, material or characteristic described in combination with the embodiment(s) or example(s) are included in at least one embodiment or example of the present disclosure. In this specification, the schematic description of the above terms does not necessarily refer to the same embodiment or example.

The technical features of the above embodiments can be employed in arbitrary combinations. In order to make the description concise, all possible combinations of all technical features of the embodiments may not be described. However, these combinations of technical features should be construed as falling within the scope defined by the specification as long as no contradiction occurs.

Only several embodiments of the present disclosure are described in detail above, but they should not therefore be construed as limiting the scope of the present disclosure. It should be noted that those of ordinary skill in the art can further make variations and improvements without departing from the conception of the present disclosure. These variations and improvements all fall within the protection scope of the present disclosure. Therefore, the protection scope of the present disclosure should be subject to the protection scope defined by the claims.

1. An electro-static discharge protection device for a semiconductor, comprising:
a substrate of a first conductive type, a deep well region of a second conductive type being formed in the substrate of the first conductive type;
a first diode, located in the deep well region of the second conductive type, an anode of the first diode being connected to a first voltage through a plurality of first metal lines;
a second diode, located in the deep well region of the second conductive type;
a first pad, connected to the anode of the first diode through the plurality of first metal lines, and connected to the first voltage;
a second pad, connected to a cathode of the second diode through a plurality of second metal lines, and connected to a second voltage; and
an input/output pad, connected to an anode of the second diode and a cathode of the first diode through a plurality of third metal lines.

2. The electro-static discharge protection device for a semiconductor according to claim 1, further comprising: a protective ring, wherein the deep well region of the second conductive type is located in the protective ring, and the protective ring is of the first conductive type.

3. The electro-static discharge protection device for a semiconductor according to claim 1, further comprising: a doped well region of the first conductive type and a doped well region of the second conductive type, wherein both the doped well region of the first conductive type and the doped well region of the second conductive type are located in the deep well region of the second conductive type, the first diode is located in the doped well region of the first conductive type, and the second diode is located in the doped well region of the second conductive type.

4. The electro-static discharge protection device for a semiconductor according to claim 3, wherein the doped well region of the first conductive type abuts against the doped well region of the second conductive type.

5. The electro-static discharge protection device for a semiconductor according to claim 3, wherein the first diode comprises a first doped region of the first conductive type and a second doped region of the second conductive type, the first doped region serving as the anode of the first diode, and the second doped region serving as the cathode of the first diode; and
the second diode comprises a third doped region of the second conductive type and a fourth doped region of the first conductive type, the fourth doped region serving as the anode of the second diode, and the third doped region serving as the cathode of the second diode.

6. The electro-static discharge protection device for a semiconductor according to claim 5, wherein the first doped regions and the second doped regions of the first diodes are alternately arranged along a first direction; and the third doped regions and the fourth doped regions of the second diodes are alternately arranged along the first direction.

7. The electro-static discharge protection device for a semiconductor according to claim 6, wherein the first metal lines are located on the first diode, and extend along the first direction; the second metal lines are located on the second diode, and extend along the first direction; and the third metal lines are located on the first diode and the second diode, and extend along the first direction.

8. The electro-static discharge protection device for a semiconductor according to claim 7, wherein the first metal lines are in one-to-one correspondence with the second metal lines, and the first metal lines and the second metal lines are alternately arranged with the third metal lines along a second direction; and the second direction is perpendicular to the first direction.

9. The electro-static discharge protection device for a semiconductor according to claim 8, further comprising: a fourth metal line, extending along the second direction, and connected to the plurality of first metal lines to form an interdigital structure with the first metal lines.

10. The electro-static discharge protection device for a semiconductor according to claim 6, further comprising: a fifth doped region of the first conductive type, located in the deep well region of the second conductive type, and around the first diode and the second diode, wherein the first doped regions enclose a plurality of first annular shapes, the second doped region being located in the first annular shape; and the third doped regions and the fifth doped region are connected to jointly enclose a plurality of second annular shapes, the fourth doped region being located in the second annular shape.

11. The electro-static discharge protection device for a semiconductor according to claim 10, wherein each of the first annular shapes is provided therein with one of the second doped regions, and each of the second annular shapes is provided therein with one of the fourth doped regions.

12. The electro-static discharge protection device for a semiconductor according to claim 10, wherein each of the first annular shapes is provided therein with a plurality of the second doped regions, and the plurality of the second doped regions located in a same first annular shape extend along a second direction, and are spaced apart along the second direction; each of the second annular shapes is provided therein with a plurality of the fourth doped regions, and the plurality of the fourth doped regions located in a same second annular shape extend along the second direction, and are spaced apart along the second direction; and the second direction is perpendicular to the first direction.

13. The electro-static discharge protection device for a semiconductor according to claim 5, wherein a shallow trench isolation structure is respectively provided between the first doped region and the second doped region, between the first doped region and the third doped region, and between the third doped region and the fourth doped region.

14. The electro-static discharge protection device for a semiconductor according to claim 1, wherein the first voltage is a power voltage, and the second voltage is a ground voltage; or the first voltage is the ground voltage, and the second voltage is the power voltage.

15. The electro-static discharge protection device for a semiconductor according to claim 1, wherein there are a plurality of the first diodes that are sequentially connected in series; and there are a plurality of the second diodes that are sequentially connected in series.

16. The electro-static discharge protection device for a semiconductor according to claim 1, wherein at least one of the first pad, the second pad and the input/output pad is of a mesh-like shape.
